(19) United States
(12) Patent Application Publication
(10) Pub. No.: US 2002/0182865 A1
(43) Pub. Date: Dec. 5, 2002

(54) Plasma processing apparatus and method for forming thin films using the same

(76) Inventors: Young Suk Lee, Kyunggi-do (KR); Young Mook Kang, Kyunggi-do (KR); Sang Do Lee, Kyunggi-do (KR)

Correspondence Address: Marger Johnson & Mccollom, 1030 S W Morrison Street, Portland, OR, 97205, US

(21) Appl. No.: 09/914,306

(22) PCT Filed: Dec. 23, 2000
(86) PCT No.: PCT/KR00/01531

(30) Foreign Application Priority Data
Dec. 24, 1999 (KR) 1999-61858

(51) Int. Cl. H01L 21/302; H01L 21/461

(52) U.S. Cl. 438/689

(57) ABSTRACT

A semiconductor device manufacturing apparatus using plasma and a thin film forming method using the apparatus. The apparatus comprises a chamber provided with an inlet and an outlet of gas, the chamber having an upper part with a dome configuration; a susceptor provided in the chamber to permit a wafer to be placed thereon; and a plasma electrode to which RF power is applied to form plasma in the chamber; wherein the plasma electrode has a dome configuration to cover the upper part, and wherein the upper polar part of the electrode is cut horizontally to form an opening. According to the present invention, it is possible to form thin film having not only good thickness uniformity but also excellent film quality.

### TECHNICAL FIELD

The present invention is related to a semiconductor device manufacturing apparatus and a thin film forming method using the apparatus, in particular to a semiconductor device manufacturing apparatus using plasma and a thin film forming method using the apparatus.

### BACKGROUND ART

Many semiconductor device manufacturing processes using plasma have been developed because a PECVD(i.e., plasma enhanced chemical vapor deposition) process, an anisotropic etching process, and the like may be carried out easily by simply applying relative bias to a plasma electrode or a susceptor when using plasma. In particular, since reacting gases are activated by plasma in the case of the PECVD process, the PECVD process using plasma has lower deposition temperature and faster deposition velocity than a LPCVD(i.e., low pressure chemical vapor deposition) process has, and therefore it is often applied to a IMD(i.e., inter metal dielectric) film forming process or a passivation film process.

When manufacturing a semiconductor device by using plasma, process uniformity is greatly dependent to plasma uniformity formed in a reaction chamber. It is most important, therefore, to enhance plasma uniformity when carrying out various processes such as PECVD, anisotropic etching, and like using plasma.

FIG. 1 is a schematic view for illustrating a semiconductor device manufacturing apparatus which is applied with a conventional CCP(i.e., capacitive coupled plasma) type plasma electrode, wherein illustration of the overall structure of the apparatus is omitted for the clarity of the description. Referring to FIG. 1, a chamber(not shown) is provided with an inlet and an outlet of gas for forming plasma, and has an upper part having a dome configuration which is made with quartz. Over the outer side of the quartz dome, a plasma electrode 10 is provided. Therefore, the plasma electrode 10 has also a dome configuration. The plasma electrode 10 is provided with a dome configuration, because the more effective area the plasma electrode has the more acceptive it is to a HDP(i.e., high density plasma) process.

A wafer 30 is placed on a susceptor 20 provided within the reaction chamber, with the susceptor 20 being grounded to serve as a corresponding electrode of the plasma electrode 10. When plasma forming gas is injected through the gas inlet and RF(i.e., radio frequency) power 40 is applied to the plasma electrode 10, plasma 50 is generated between the susceptor 20 and the plasma electrode 10.

FIG. 2A to FIG. 2C are drawings for illustrating thickness uniformity of thin film deposited on the wafer by a semiconductor device manufacturing apparatus of FIG. 1, wherein FIG. 2A is a graph showing plasma density according to horizontal position within the chamber, FIG. 2B and FIG. 2C are drawings showing resultant thin films 30′, 30″ deposited on the wafer 30, respectively.

In description in association with FIG. 1, the plasma electrode 10 is provided with more effective electrode area in its polar part than its side due to the dome configuration thereof. Therefore, as shown in FIG. 2A, plasma with higher density is formed in a central region than in a peripheral region, and the thin film 30 formed in the central region has more thickness than that in the peripheral region as shown in FIG. 2B. However, if RF power 40 which is applied to the plasma electrode 10 is too weak, thin film deposited in the central region has less thickness. Therefore, thin film with good thickness uniformity may be achieved by adjusting the strength of RF power 40 properly in a state between FIG. 2B and FIB. 2C. In this case, however, there is a problem that the range of RF power 40 is too narrow in which this thin film may be formed. When forming Siₓ N_{y} film, for example, disadvantages of the conventional semiconductor device manufacturing apparatus are described more in detail as follows:

At first, even in the case of forming Siₓ N_{y} film by the PECVD method having above mentioned advantages compared to the LPCVD, formed Siₓ N_{y} film should meet the following requirements similarly to the film formed by the LPCVD method: (1) thin film should contain only little amount of hydrogen, and (2) have excellent thickness uniformity, etc.

Returning to the main subject, the process of forming Siₓ N_{y} film by the PECVD method is described.

Siₓ N_{y} film is formed by supplying mixed gas of SiH₄ and NH₃ into the chamber and then making the gas into plasma state to be deposed on the wafer. In this case, hydrogen atoms are not completely decomposed if RF power is weak, therefore SiH₄ gas resides in the form of SiH *, SiH₂* or SiH₃* radical and NH₃ gas resides in the form of NH* or NH₂* radical. Therefore, the hydrogen is contained in the deposited Siₓ N_{y} film in the form of SiH *, SiH₂, SiH₃, NH *, or NH₂, thereby giving bad influences such as changing the threshold voltage of the transistor.

In order to improve this, strong RF power should be applied so that hydrogen atoms may completely decomposed to evaporate in gas state. However, under this RF power strength, the state corresponds to that of FIB. 2B and therefore thickness uniformity declines. Therefore, it is difficult to form thin film having not only good thickness uniformity but also excellent film quality according to the conventional semiconductor device manufacturing apparatus and the thin film forming method using the apparatus.

### DISCLOSURE OF THE INVENTION

It is, therefore, and object of the present invention to provide a semiconductor device manufacturing apparatus which may form thin film having not only good thickness uniformity but also excellent film quality.

Another object of the present invention is to provide a thin film forming method using the semiconductor device manufacturing apparatus which is provided by the above mentioned object of the present invention.

According to one embodiment to achieve the first object of the present invention, a semiconductor device manufacturing apparatus is provided, the apparatus comprising: a chamber provided with an inlet and an outlet of gas, the chamber having an upper part with a dome configuration; a susceptor provided in the chamber to permit a wafer to be placed thereon; and a plasma electrode to which RF power is applied to generate plasma within the chamber; wherein the plasma electrode has a dome configuration to cover the upper part, and wherein the upper polar part of the electrode is cut horizontally to form an opening.

According to one embodiment to achieve the second object of the present invention, a thin film forming method using the semiconductor device manufacturing apparatus according to the first object of the present invention is provided; wherein the plasma electrode is applied with RF power of about 700 to 1000W whereby Siₓ N_{y} thin film has good thickness uniformity while containing less amount of hydrogen when using hydrogen containing plasma to form the Siₓ N_{y} thin film.

Preferably, the plasma is generated by mixed gas of SiH₄ and NH₃.

By means of the semiconductor device manufacturing apparatus and the thin film forming method using the apparatus according to the present invention, it is possible to form thin film having not only good thickness uniformity but also excellent film quality.

### BRIEF DESCRIPTION OF THE DRAWINGS

FIG. 1 is a schematic view for illustrating a semiconductor manufacturing apparatus having a CCP(i.e., capacitive coupled) plasma type plasma electrode applied thereto;

FIG. 2A to FIG. 2C are drawings for illustrating thickness uniformity of thin film deposited on a wafer by the semiconductor device manufacturing apparatus of FIG. 1;

FIG. 3 is a schematic view for illustrating a plasma electrode of the semiconductor device manufacturing apparatus according to one embodiment of the present invention; and

FIG. 4 is a graph for illustrating thickness uniformity when Siₓ N_{y} film is formed by using the semiconductor device manufacturing apparatus having the plasma electrode of FIG. 3.

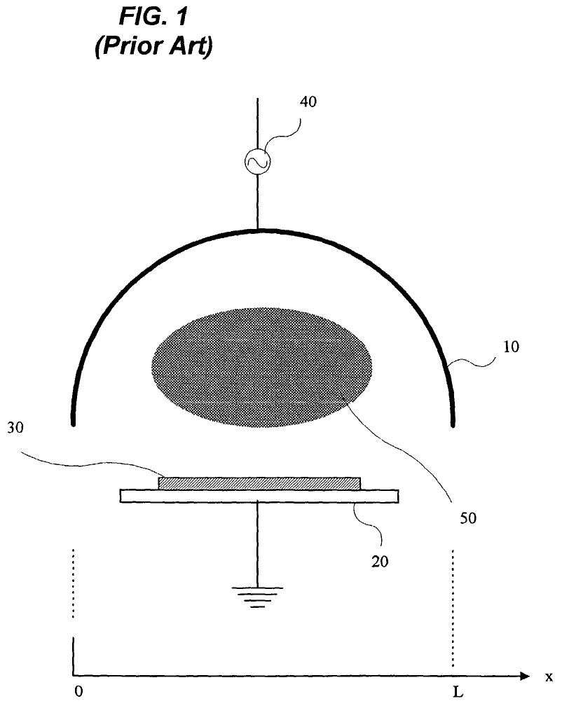

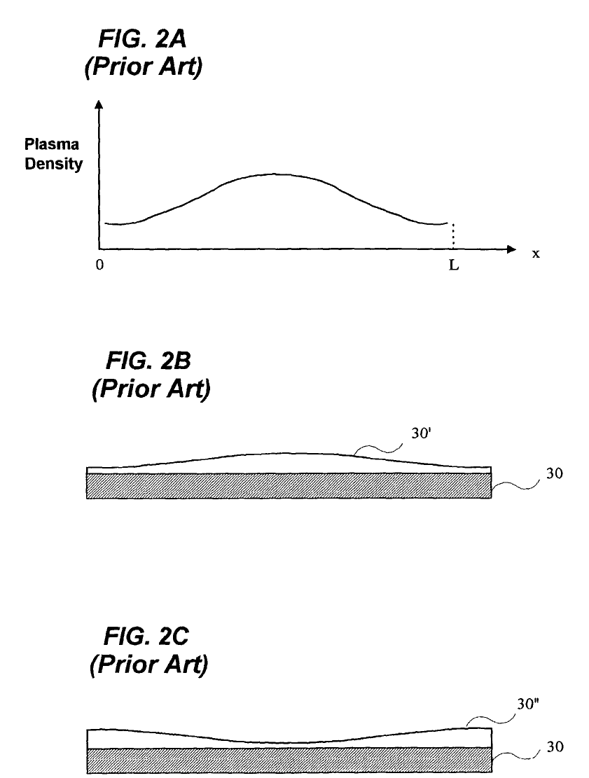

### BEST MODE FOR CARRYING OUT THE INVENTION

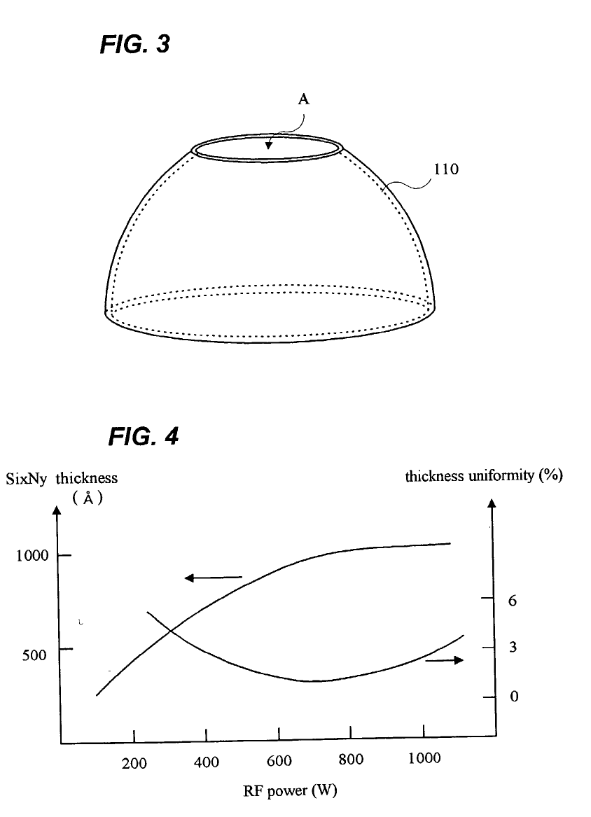

Herein after preferred embodiments of the present invention are described in detail in reference to appended drawings. Only characteristic parts of the present invention are shown in order to avoid repeated description of about the conventional arts. FIG. 3 is a schematic view for illustrating a plasma electrode 110 of the semiconductor device manufacturing apparatus according to one embodiment of the present invention. Referring to FIG. 3, the plasma electrode 110, which has a dome configuration in order to cover a quartz dome over its outside, is provided with an opening A having width of about 70 mm to 300 mm, the opening being formed by cutting the electrode 110 horizontally at its upper polar part in order to solve the conventional problem. The opening A is provided in the electrode 110 at its polar part like this for the purpose of achieving uniform density of plasma generated within the chamber.

FIG. 4 is a graph showing the result of thickness of a Siₓ N_{y} film and its uniformity measured according to strength of RF power when the Siₓ N_{y} film was formed by using the semiconductor device manufacturing apparatus which is provided with the plasma electrode 110 of FIG. 3. Herein, thickness uniformity is obtained in accordance with the following equation by measuring thicknesses of the Siₓ N_{y} film at 5 points.

thickness uniformity(%)=average value of {average value of thickness−thickness of a certain part)/average value of thickness* 100 }

Referring to FIG. 4, it may be understood that thickness of the Siₓ N_{y} film increases as applied RF power is enhanced. It may be also understood that in the range of 500W to 1000W thickness uniformity has a value in the range of 1% to 3%. Therefore,, it is possible to form Siₓ N_{y} film having excellent thickness uniformity even though applying the plasma electrode 110 with strong RF power in the degree of 700W 1000W so that hydrogen atoms are completely decomposed to evaporate in gas state. Therefore, it is possible to form Siₓ N_{y} film not only containing little amount of hydrogen but also having excellent thickness uniformity. In turn, when forming DLC(i.e., diamond like carbon) film by using the plasma which is generated by mixed gas of CH₄ and H₂ and forming SiC thin film by using the plasma which is generated by mixed gas of SiH₄, CH₄, and H₂, it is also possible to form thin film not only containing little amount of hydrogen but also having excellent thickness uniformity by means of applying RF power in the degree of 500W to 1000W.

### Industrial Applicability

According to the semiconductor device manufacturing apparatus and the thin film forming method using the apparatus of the present invention as mentioned above, it is possible to form thin film having excellent thickness uniformity even under strong RF power. In particular, when using the apparatus of the present invention in formation of Siₓ N_{y} film, it is possible to form Si_{x l N}_{y} film having excellent thickness uniformity even though RF power is applied up to 700W to 1000W so that Siₓ N_{y} film contains only little amount of hydrogen.

Finally, according to the present invention, it is possible to easily form thin film having not only good thickness uniformity but also excellent film quality by simply changing the geometric configuration of the plasma electrode.

It should be understood that the present invention is not limited to the above mentioned embodiments, but various other modifications will be apparent to those skilled in the art without departing from the scope and spirit of the present invention.

What is claimed is:

1. A semiconductor device manufacturing apparatus comprising:
a chamber provided with an inlet and an outlet of gas, said chamber having an upper part with a dome configuration;
a susceptor provided in said chamber to permit a wafer to be placed thereon; and
a plasma electrode to which RF power is applied to generate plasma within said chamber;
wherein said plasma electrode has a dome configuration to cover said upper part, and wherein the upper polar part of said electrode is cut horizontally to form an opening.

2. The semiconductor device manufacturing apparatus according to claim 1, said opening has a width of about 70 mm to 300 mm.

3. A thin film forming method using a semiconductor device manufacturing apparatus comprising a chamber provided with an inlet and an outlet of gas, said chamber having an upper part with a dome configuration, a susceptor provided in said chamber to permit a wafer to be placed thereon, and a plasma electrode to which RF power is applied to generate plasma within said chamber, wherein said plasma electrode has a dome configuration to cover said upper part, and wherein the upper polar part of said electrode is cut horizontally to form an opening;
wherein said plasma electrode is applied with RF power of about 700W to 1000W whereby SiₓN_{y} thin film has good thickness uniformity while containing less amount of hydrogen when using hydrogen containing plasma to form said SiₓN_{y} thin film.

4. The thin film forming method according to claim 3, said hydrogen containing plasma is formed by mixed gas of SiH₄ and NH₃.

5. A thin film forming method using a semiconductor device manufacturing apparatus comprising a chamber provided with an inlet and an outlet of gas, said chamber having an upper part with a dome configuration, a susceptor provided in said chamber to permit a wafer to be placed thereon, and a plasma electrode to which RF power is applied to generate plasma within said chamber, wherein said plasma electrode has a dome configuration to cover said upper part, and wherein the upper polar part of said electrode is cut horizontally to form an opening;
wherein said plasma electrode is applied with RF power of about 500W to 1000W whereby said DLC thin film or SiC thin film has good thickness uniformity while containing less amount of hydrogen when using hydrogen containing plasma to form DLC thin film or SiC thin film.

6. The thin film forming method according to claim 5, said hydrogen containing plasma is formed by mixed gas of CH₄ and H₂ when forming said DLC thin film, and by mixed gas of SiH₄, CH₄ and H₂ when forming said SiC thin film.
